(19) United States
(12) Patent Application Publication
(10) Pub. No.: US 2026/0282809 A1
(43) Pub. Date: Sep. 17, 2026

(54) SEMICONDUCTOR MOUNTING APPARATUS AND SEMICONDUCTOR MOUNTING METHOD

(71) Applicant: Kioxia Corporation, Tokyo (JP)

(72) Inventor: Taishi NAKAHARA, Tokyo (JP)

(73) Assignee: Kioxia Corporation, Tokyo (JP)

(21) Appl. No.: 19/232,986

(22) Filed: Jun. 10, 2025

(30) Foreign Application Priority Data
Mar. 11, 2025 (JP) 2025-038458

(51) Int. Cl. H01L 21/67; H01L 23/00

(52) U.S. Cl. CPC H10P 72/0442; H10W 72/07331

(57) ABSTRACT

According to one embodiment, a semiconductor mounting apparatus includes an electronic component holder, a substrate holder, and a mounting head. On the electronic component holder, two or more semiconductor chips having first surfaces provided with an adhesive agent are placeable. The substrate holder holds a substrate on which the two or more semiconductor chips are to be mounted. The mounting head picks up the two or more semiconductor chips from the electronic component holder, and mounts the two or more semiconductor chips on the substrate in such a manner that the first surfaces face the substrate.

### CROSS-REFERENCE TO RELATED APPLICATIONS

This application is based upon and claims the benefit of Japanese Patent Application No. 2025-038458, filed on Mar. 11, 2025; the entire contents of which are incorporated herein by reference.

### FIELD

Embodiments described herein relate generally to a semiconductor mounting apparatus and a semiconductor mounting method.

### BACKGROUND

There has been a semiconductor apparatus in which a plurality of semiconductor chips is adjacently mounted on a substrate. In a manufacturing process of such a semiconductor apparatus, the semiconductor chips having bottom surfaces with adhesive agents applied thereon are sequentially placed on the substrate.

At this time, an adhesive layer sometimes protrudes from the bottom surface of one semiconductor chip placed on the substrate. The protruding adhesive layer sometimes inhibits other semiconductor chips from being appropriately mounted on the substrate.

### BRIEF DESCRIPTION OF THE DRAWINGS

FIG. 1 is a diagram illustrating an example of a configuration of a semiconductor mounting apparatus of a first embodiment;

FIGS. 2A to 2C are diagrams exemplifying a part of a flow of semiconductor mounting processing in the first embodiment;

FIGS. 3A and 3B are diagrams illustrating an example of a flow of first adjustment processing according to the first embodiment;

FIGS. 4A and 4B are diagrams exemplifying a part of a flow of semiconductor mounting processing in the first embodiment;

FIGS. 5A to 5D are diagrams exemplifying a part of a flow of a manufacturing method of a semiconductor apparatus to which the semiconductor mounting processing of the first embodiment;

FIG. 6 is a diagram illustrating an example of a configuration of a preciser of Modified Example 1 of the first embodiment;

FIGS. 7A to 7E are diagrams illustrating an example of a flow of second adjustment processing in Modified Example 1 of the first embodiment;

FIGS. 8A to 8E are diagrams illustrating an example of a flow of second adjustment processing in Modified Example 2 of the first embodiment;

FIG. 9 is a diagram illustrating an example of a configuration of a semiconductor mounting apparatus of a second embodiment;

FIGS. 10A and 10B are diagrams illustrating an example of a configuration of a mounting head of the second embodiment;

FIG. 11Aa to 11Cb are diagrams illustrating an example of a flow of third adjustment processing in the second embodiment;

FIG. 12 is a diagram illustrating an example of a configuration of a mount apparatus of Modified Example 1 of the second embodiment;

FIG. 13Aa to 13Cb are diagrams illustrating an example of a flow of fourth adjustment processing in Modified Example 1 of the second embodiment;

FIG. 14Aa to 14Cb are diagrams illustrating an example of a flow of fourth adjustment processing in Modified Example 2 of the second embodiment;

FIG. 15 is a diagram illustrating an example of a configuration of a semiconductor mounting apparatus of a third embodiment; and

FIGS. 16A to 16C are diagrams illustrating an example of a flow of fifth adjustment processing in the third embodiment.

### DETAILED DESCRIPTION

In general, according to one embodiment, a semiconductor mounting apparatus includes an electronic component holder, a substrate holder, and a mounting head. On the electronic component holder, two or more semiconductor chips having first surfaces provided with an adhesive agent are placeable. The substrate holder holds a substrate on which the two or more semiconductor chips are mounted. The mounting head picks up the two or more semiconductor chips from the electronic component holder, and mounts the picked-up two or more semiconductor chips on the substrate in such a manner that the first surfaces face the substrate.

Hereinafter, a semiconductor mounting apparatus and a semiconductor mounting method according to an embodiment will be described in detail with reference to the accompanying drawings. In addition, the present invention is not limited to these embodiments.

### First Embodiment

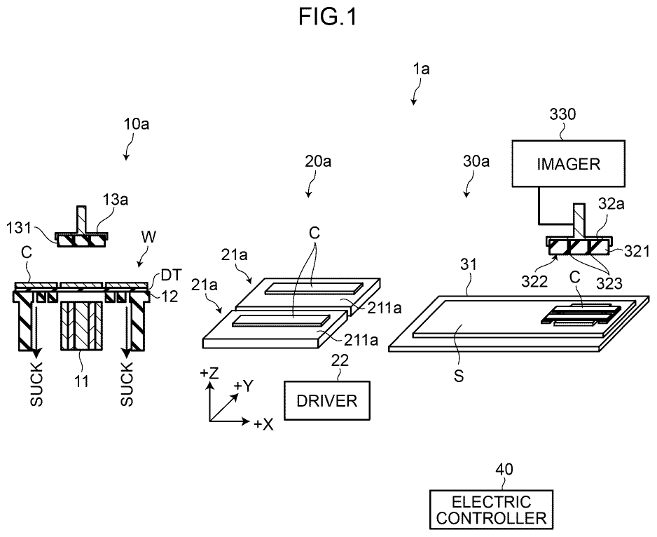

Hereinafter, the first embodiment will be described using FIGS. 1 to 5D.

FIG. 1 is a diagram illustrating an example of a configuration of a semiconductor mounting apparatus 1a of the first embodiment.

As illustrated in FIG. 1, the semiconductor mounting apparatus 1a includes a pickup apparatus 10a, a preciser 20a, a mount apparatus 30a, and an electric controller 40.

The pickup apparatus 10a is an apparatus that picks up a singulated semiconductor chip C from a dicing tape DT. Specifically, the pickup apparatus 10a includes a thrusting mechanism 11, a wafer holder 12, and a transfer head 13a.

The thrusting mechanism 11 thrusts up a semiconductor chip C to be thrust, from a plurality of semiconductor chips C singulated from a semiconductor wafer W. The thrusting mechanism 11 thrusts up the semiconductor chip C to be thrust.

The wafer holder 12 is arranged around the thrusting mechanism 11, and holds the semiconductor chips C around the semiconductor chip C to be thrust by the thrusting mechanism 11. Specifically, the wafer holder 12 includes a suction hole through which the rear surface of the dicing tape DT can be sucked. By sucking the rear surface of the dicing tape DT, the wafer holder 12 holds the semiconductor chips C around the semiconductor chip C to be thrust.

The transfer head 13a picks up the semiconductor chip C thrust by the thrusting mechanism 11. The transfer head 13a includes a suction collet 131 that can suck the semiconductor chip C. The semiconductor chip C is held by being sucked by the suction collet 131.

The transfer head 13a transfers the picked-up semiconductor chip C to the preciser 20a. The transfer head 13a places the semiconductor chip C on the preciser 20a.

The preciser 20a places the semiconductor chip C transferred by the transfer head 13a, and delivers the semiconductor chip C to the mount apparatus 30a. That is, the preciser 20a is a delivery stand that delivers the semiconductor chip C between the pickup apparatus 10a and the mount apparatus 30a. Further, the preciser 20a has a function of adjusting an inter-chip distance of a plurality of placed semiconductor chip C, which will be described in detail later. The preciser 20a is an example of an electronic component holder.

Specifically, the preciser 20a includes a plurality of stages 21a, and a driver 22 that drives the stages 21a.

The plurality of stages 21a is each formed into an approximately rectangular shape in a top view, for example, and is arranged adjacently in a predetermined direction. The plurality of stages 21a each individually has a placement surface 211a on which the semiconductor chip C can be placed.

Each of the placement surfaces 211a is provided with a sucker (not illustrated) that can suck the semiconductor chip C. With this configuration, the semiconductor chip C is held by being sucked to the placement surface 211a. The placement surface 211a is an example of a first placement surface.

In addition, in this specification, hereinafter, a predetermined direction extending along the placement surface 211a will be referred to as a Y direction. The Y direction also serves as a direction in which the plurality of stages 21a is arranged. Further, a direction that extends along the placement surface 211a and is orthogonal to the Y direction will be referred to as an X direction, and a direction orthogonal to the X direction and the Y direction will be referred to as a Z direction. The direction of an arrow of each axis will be referred to as a positive direction, and an opposite direction will be referred to as a negative direction. Further, a direction that extends along the Z direction will be referred to as an up-down direction, the positive direction side of the Z direction will be referred to as an up direction, and the negative direction side of the Z direction will be referred to as a down direction. The Y direction is an example of a first direction, and the X direction is an example of a second direction.

The driver 22 is an actuator including a motor (not illustrated) and the like. The driver 22 moves each of the plurality of stages 21a in the X direction and the Y direction. In accordance with an instruction from the electric controller 40, the driver 22 controls operations in the X direction and the Y direction of the plurality of stages 21a. With this configuration, it is possible to adjust an inter-chip distance of the plurality of semiconductor chips C placed on the respective placement surfaces 211a. The driver 22 is an example of a first driver.

Hereinafter, adjustment processing of an inter-chip distance of the plurality of semiconductor chips C on the placement surfaces 211a will be sometimes referred to as “first adjustment processing”. The details of the first adjustment processing will be described later.

The mount apparatus 30a is an apparatus that picks up the plurality of semiconductor chips C from the placement surfaces 211a, and places the picked-up plurality of semiconductor chips C on a substrate S. Specifically, the mount apparatus 30a includes a substrate holder 31 and a mounting head 32a.

The substrate holder 31 holds the substrate S on which the plurality of semiconductor chips C is to be mounted. The substrate holder 31 includes a heater (not illustrated) serving as a heater, on the bottom surface side. The heater heats the substrate S held by the substrate holder 31. The plurality of semiconductor chips C placed on the substrate S is thereby heated.

The mounting head 32a picks up the semiconductor chips C from the plurality of respective placement surfaces 211a, and transfers the plurality of picked-up semiconductor chips C to the substrate holder 31. The mounting head 32a mounts the plurality of semiconductor chips C moved up to the substrate holder 31, on the substrate S. The plurality of semiconductor chips C is placed in such a manner that their bottom surfaces face the substrate S.

Specifically, the mounting head 32a includes a suction collet 321 that can suck the plurality of semiconductor chips C. A suction hole 323 is provided on a bottom surface 322 of the suction collet 321. The suction hole 323 connects with a vacuum pump (not illustrated). With this configuration, the plurality of semiconductor chips C is held by being sucked to the bottom surface 322 of the suction collet 321. At this time, the plurality of semiconductor chips C is held with their bottom surfaces oriented downward.

Further, the mounting head 32a includes an imager 330. For example, the imager 330 is a camera, and is attached to an upper part of the mounting head 32a. The imager 330 captures the plurality of semiconductor chips C placed on the placement surfaces 211a, from above. Before the plurality of semiconductor chips C is sucked by the suction collet 321, the imager 330 performs the above-described image capturing. The imager 330 transmits the captured image to the electric controller 40. The captured image is used for first adjustment processing in the electric controller 40. The imager 330 is an example of a first imager.

The electric controller 40 is formed as a computer including, for example, a hardware processor such as a central processing unit (CPU), a memory, a hard disk drive (HDD), and the like. The electric controller 40 executes semiconductor mounting processing in accordance with various programs stored in the memory. The electric controller 40 controls each component of the semiconductor mounting apparatus 1a in executing the semiconductor mounting processing.

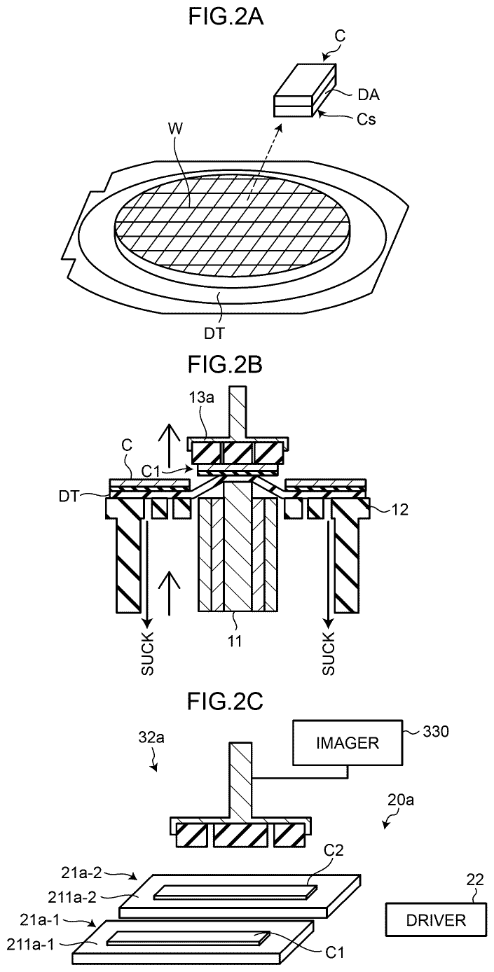

Next, a flow of the semiconductor mounting processing will be described using FIGS. 2A to 4B.

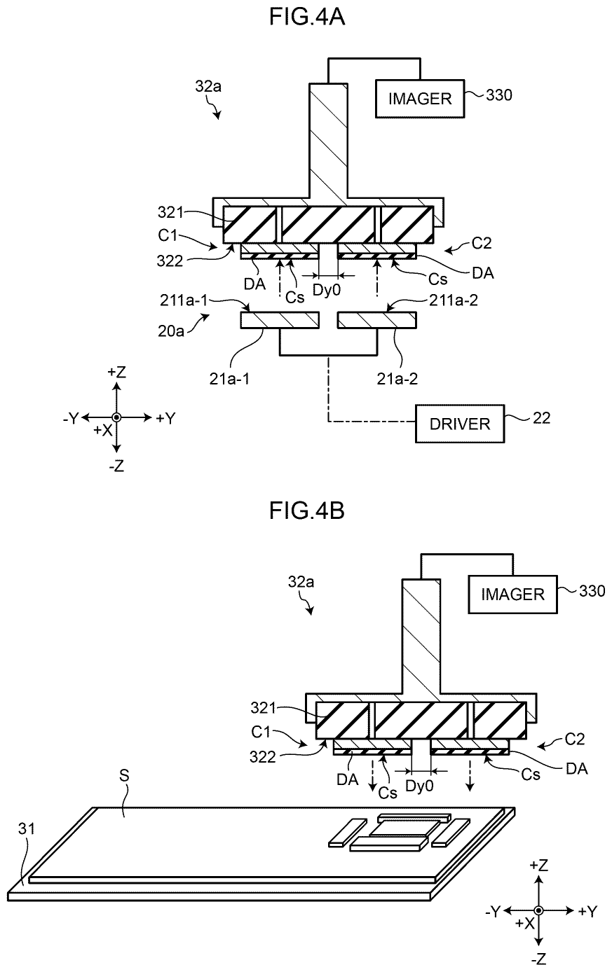

FIGS. 2A to 2C and FIGS. 4A and 4B are diagrams exemplifying a part of a flow of the semiconductor mounting processing in the first embodiment.

As illustrated in FIG. 2A, the semiconductor wafer W is singulated into the plurality of semiconductor chips C. The semiconductor wafer W is singulated with being stuck to the dicing tape DT via an adhesive agent DA.

The adhesive agent DA is also called a die attach film (DAF), for example, and is a thermoset resin agent molded into a film shape. When the semiconductor wafer W is singulated into the semiconductor chips C, the adhesive agent DA is cut out together with a bottom surface Cs of the semiconductor chip C. The adhesive agent DA has predetermined flexibility at normal temperature, and curs by being heated. The adhesive agent DA has a role of bonding the semiconductor chip C to the substrate S.

In addition, in this specification, hereinafter, the semiconductor chip C and the adhesive agent DA provided on the bottom surface Cs of the semiconductor chip C will be sometimes collectively referred to as the semiconductor chip C. The bottom surface Cs is an example of a first surface.

Subsequently, as illustrated in FIG. 2B, the wafer holder 12 holds the semiconductor chips C around the semiconductor chip C to be thrust. The thrusting mechanism 11 thrusts up the semiconductor chip C to be thrust.

In a case where there is a plurality of semiconductor chips C to be thrust, the thrusting mechanism 11 thrusts up the plurality of semiconductor chips C one by one. Specifically, for example, the thrusting mechanism 11 thrusts up a semiconductor chip C1 from the plurality of semiconductor chips C. If the semiconductor chip C1 is picked up by the transfer head 13a, the thrusting mechanism 11 thrusts up a semiconductor chip C2.

The transfer head 13a places the picked-up semiconductor chip C1 on a placement surface 211a-1. After the transfer head 13a places the semiconductor chip C1 on the placement surface 211a-1, the transfer head 13a returns to the pickup apparatus 10a, picks up the semiconductor chip C2 thrust next, and places the semiconductor chip C2 on a placement surface 211a-2. In this manner, the transfer head 13a picks up the semiconductor chips C one by one from the thrusting mechanism 11, and sequentially places the semiconductor chips C on the placement surfaces 211a. The transfer head 13a picks up the thrust semiconductor chips C1 and C2 by sucking the semiconductor chips C1 and C2.

Further, for example, the thrusting mechanism 11 may simultaneously thrust up the two semiconductor chips C1 and C2. In this case, the transfer head 13a simultaneously thrusts up the two semiconductor chips C1 and C2. Then, the transfer head 13a places the picked-up semiconductor chips C1 and C2 respectively on the placement surfaces 211a-1 and 211a-2 one by one.

Nevertheless, the transfer head 13a may simultaneously place the two picked-up semiconductor chips C1 and C2 on the placement surfaces 211a-1 and 211a-2.

Further, in this specification, hereinafter, the description will be continued assuming that the two semiconductor chips C1 and C2 are placed on the preciser 20a, but the number of semiconductor chips C is not limited to this. Three or more semiconductor chips C may be placed on the preciser 20a. In this case, the first adjustment processing to be described later is executed on three or more placed semiconductor chips C.

In addition, in this specification, in a case where there is no need to make a distinction between the semiconductor chips C1 and C2, hereinafter, the semiconductor chips C1 and C2 will be sometimes collectively referred to as the semiconductor chips C.

Subsequently, in FIG. 2C, the electric controller 40 executes the first adjustment processing of adjusting an inter-chip distance of the semiconductor chips C1 and C2 respectively placed on the placement surfaces 211a-1 and 211a-2. The first adjustment processing is performed as part of the semiconductor mounting processing.

### Flow of First Adjustment Processing

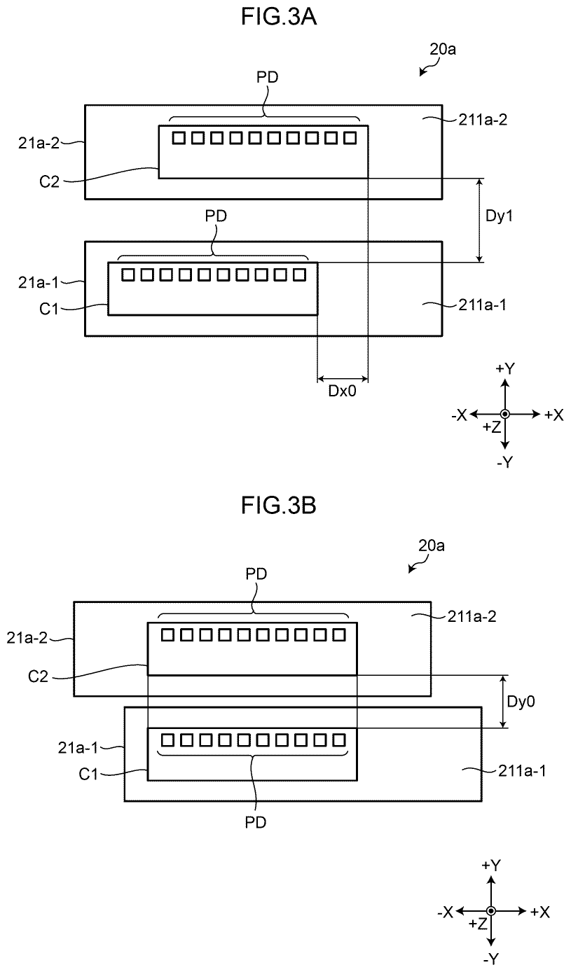

FIGS. 3A and 3B are diagrams illustrating an example of a flow of the first adjustment processing in the first embodiment. More specifically, FIGS. 3A and 3B are plan views of the placement surfaces 211a-1 and 211a-2 on which the semiconductor chips C are placed that are viewed from above.

In addition, in the example in FIGS. 3A and 3B, the description will be given assuming that, in accordance with the number of semiconductor chips C, the preciser 20a includes two stages 21a (the placement surfaces 211a), but the number of stages 21a is not limited to this. The number of stages 21a can be arbitrarily changed in accordance with the number of semiconductor chips C to be placed.

As illustrated in FIG. 3A, stages 21a-1 and 21a-2 of the preciser 20a are arranged adjacently in the Y direction. In the example in FIG. 3A, the stage 21a-1 is arranged on the negative direction side of the Y direction, and the stage 21a-2 is arranged on the positive direction side in the Y direction. The semiconductor chip C1 is placed on the placement surface 211a-1 of the stage 21a-1, and the semiconductor chip C2 is placed on the placement surface 211a-2 of the stage 21a-2.

Each of the semiconductor chips C1 and C2 is a small piece singulated from a silicon (Si) substrate or the like, and has a built-in nonvolatile memory such as a NOT-AND (NAND) flash memory, for example. At the end on one side of each of the top surface of the semiconductor chip C1 and the top surface of the semiconductor chip C2, a plurality of electrode pads PD for electrically drawing the built-in nonvolatile memory is provided. The semiconductor chips C1 and C2 are respectively placed on the placement surfaces 211a-1 and 211a-2 with their ends on the side on which the electrode pads PD are arranged, being oriented toward the positive direction side of the Y direction.

In FIG. 3A, the imager 330 (FIG. 2C) captures the semiconductor chips C1 and C2 from above the stages 21a-1 and 21a-2. The imager 330 transmits the captured image of the semiconductor chips C1 and C2 to the electric controller 40.

Based on the captured image, the electric controller 40 identifies a positional relationship of the semiconductor chips C1 and C2. The positional relationship of the semiconductor chips C1 and C2 is a (current) inter-chip distance of the semiconductor chips C1 and C2 in the preciser 20a, for example.

The electric controller 40 controls the driver 22 based on the identified current inter-chip distance of the semiconductor chips C1 and C2, and design information indicating an ideal inter-chip distance of the semiconductor chips C1 and C2 to be placed on the substrate S, and moves at least either one of the stages 21a-1 and 21a-2 in at least either of the X direction and the Y direction. The design information is prestored in a memory or the like of the semiconductor mounting apparatus 1a.

For example, it is assumed that an ideal inter-chip distance in the Y direction of the semiconductor chips C1 and C2 is “Dy0”, and an ideal inter-chip distance in the X direction is “0” (i.e., state in which the positions in the X direction of the semiconductor chips C1 and C2 are equal). In contrast to this, as illustrated in FIG. 3A, it is assumed that the current inter-chip distance in the Y direction of the semiconductor chips C1 and C2 is “Dy1, and an inter-chip distance in the X direction is “Dx0” (i.e., state in which the semiconductor chips C1 and C2 are shifted in the X direction by “Dx0”).

As illustrated in FIG. 3B, the electric controller 40 controls the driver 22 to move the stage 21a-1 toward the positive direction side of the X direction and the positive direction side of the Y direction, for example. With this configuration, it is possible to change the current inter-chip distance of the semiconductor chips C1 and C2 to an ideal inter-chip distance that is based on the design information.

Through the above-described process, the first adjustment processing ends. According to the first adjustment processing, it is possible to adjust an inter-chip distance of the semiconductor chips C1 and C2 on the substrate S.

If the first adjustment processing ends, as illustrated in FIG. 4A, the mounting head 32a picks up the semiconductor chips C1 and C2 respectively from the placement surfaces 211a-1 and 211a-2. Specifically, the mounting head 32a brings the bottom surface 322 of the suction collet 321 close to the placement surfaces 211a-1 and 211a-2, and simultaneously sucks the semiconductor chips C1 and C2 to the bottom surface 322. With this configuration, the semiconductor chips C1 and C2 are sucked to the bottom surface 322 of the suction collet 321 in a state in which an ideal inter-chip distance (e.g., “Dy0”) is maintained.

Nevertheless, the mounting head 32a needs not always simultaneously suck the semiconductor chips C1 and C2. For example, the mounting head 32a may suck the semiconductor chips C1 and C2 one by one from the respective placement surfaces 211a-1 and 211a-2. Nevertheless, in this case, after a first semiconductor chip C is picked up, the mounting head 32a does not move in the X direction and the Y direction. This is to prevent an inter-chip distance of the semiconductor chips C1 and C2 that has been adjusted in the first adjustment processing, from varying.

Subsequently, as illustrated in FIG. 4B, the mounting head 32a lowers toward the substrate S held on the top surface of the substrate holder 31, and pushes the bottom surface 322 of the suction collet 321 against a predetermined position of the substrate S. With this configuration, the semiconductor chips C1 and C2 are pushed against the substrate S. The semiconductor chips C1 and C2 are simultaneously placed on the substrate S in a state in which an ideal inter-chip distance (e.g., “Dy0”) adjusted by the first adjustment processing is maintained.

Subsequently, the semiconductor chips C1 and C2 are heated by a heater (not illustrated) provided in the substrate holder 31, and the adhesive agent DA cures. With this configuration, the semiconductor chips C1 and C2 are bonded to the substrate S. Through the above-described process, the semiconductor mounting processing ends.

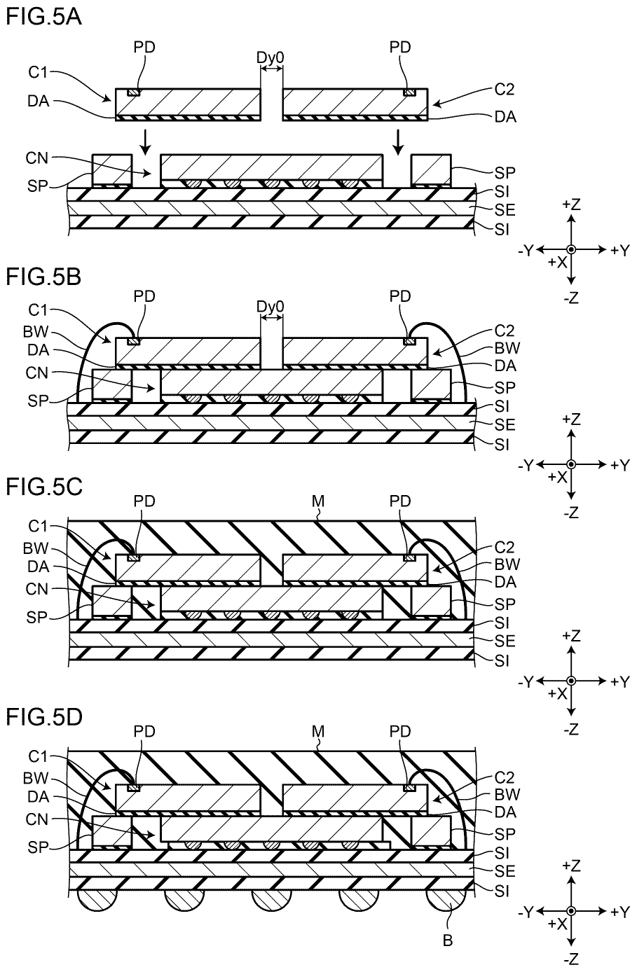

A manufacturing method of a semiconductor apparatus to which the above-described semiconductor mounting processing is applied will be described using FIGS. 5A to 5D. The above-described semiconductor mounting processing is performed as part of the manufacturing method of a semiconductor apparatus.

FIGS. 5A to 5D are diagrams exemplifying a part of a flow of the manufacturing method of a semiconductor apparatus to which the semiconductor mounting processing of the first embodiment is applied.

In addition, in FIGS. 5A to 5D, the semiconductor chips C1 and C2 are placed on the placement surfaces 211a-1 and 211a-2 with the ends on the side on which the electrode pads PD are arranged, being oriented respectively toward the positive and negative directions of the Y direction.

The substrate S on which the semiconductor chips C1 and C2 are to be mounted is a lead frame, a wiring substrate, or the like, for example, and as illustrated in FIG. 5A, has a configuration in which a controller CN and a spacer SP are arranged on the top surface. The controller CN has a built-in integrated circuit that can control the operation of the semiconductor chip C. The spacer SP is a small piece of a Si substrate or the like, and supports the plurality of semiconductor chips C on its top surface.

Further, the substrate S has a multitiered configuration in which insulation layers SI and conductive layers SE are alternately stacked. The conductive layers SE have a wiring pattern (not illustrated, and connect with the above-described controller CN, and an electrode (not illustrated) that is exposed from an uppermost insulation layer SI.

By the semiconductor mounting processing described using FIGS. 2A to 4B, the semiconductor chips C1 and C2 are simultaneously placed on the controller CN and the spacer SP. The semiconductor chips C1 and C2 have an ideal inter-chip distance “Dy0” that is based on the design information.

Subsequently, as illustrated in FIG. 5B, a bonding wire BW that electrically connects the electrode pad PD of the semiconductor chip C, and an electrode (not illustrated) that is exposed to an uppermost insulation layer SI is formed. With this configuration, the semiconductor chip C and the conductive layer SE of the substrate S are electrically connected.

Subsequently, as illustrated in FIG. 5C, a mold resin M covering the semiconductor chips C and the bonding wire BW is formed.

Subsequently, as illustrated in FIG. 5D, the semiconductor chips C are singulated, and metal bumps B are formed on the bottom surface of the substrate S. The metal bumps B are solder balls, for example.

Through the above-described process, the semiconductor apparatus of the first embodiment is completed.

### Sum-Up

Meanwhile, if the semiconductor chip C is pushed against the substrate S by the mounting head 32a, the adhesive agent DA sometimes protrudes from the bottom surface of the semiconductor chip C sandwiched between the mounting head 32a and the substrate S.

For this reason, if the semiconductor chips C are sequentially placed on the substrate S one by one, for example, a different semiconductor chip C is sometimes placed on the adhesive agent DA protruding from a semiconductor chip C placed on the substrate S earlier. With this configuration, in some cases, the different semiconductor chip C is inclined on the substrate S, or is broken by being pushed against the mounting head 32a from above in an inclined state. Further, if the different semiconductor chip C is placed on the substrate S in the inclined state, the adhesive agent DA fails to wetly spread on the substrate S, and the semiconductor chip C sometimes fails to be bonded to the substrate S.

Furthermore, in recent years, a reduction in an area of a semiconductor apparatus has been demanded. If an area of a semiconductor apparatus is reduced, an inter-chip distance of a plurality of semiconductor chips C mounted on the semiconductor apparatus is also shortened. If the inter-chip distance is shortened, there is concern that the adhesive agent DA protruding from the semiconductor chip C placed on the substrate S earlier exerts larger influence on the different semiconductor chip C.

In order to solve the above-described problem, the semiconductor mounting apparatus 1a of the first embodiment includes the preciser 20a on which a plurality of semiconductor chips C can be placed, and the mounting head 32a that picks up the plurality of semiconductor chips C from the preciser 20a, and mounts the plurality of picked-up semiconductor chips C on the substrate S.

With this configuration, it is possible to simultaneously place the plurality of semiconductor chips C on the substrate S. By simultaneously placing the plurality of semiconductor chips C on the substrate S, it is possible to avoid placing a different semiconductor chip C on the adhesive agent DA protruding from the bottom surface of a semiconductor chip C placed on the substrate S earlier. It is therefore possible to prevent the inclination or breakage of the semiconductor chip C on the substrate S, a bond failure with respect to the substrate S, and the like, which have been described above.

In this manner, according to the semiconductor mounting apparatus 1a of the first embodiment, because it is possible to prevent a semiconductor chip C placed on the substrate S earlier, from affecting a different semiconductor chip C, it becomes possible to appropriately mount a plurality of semiconductor chips C on the substrate S.

Further, because it is possible to appropriately mount the plurality of semiconductor chips C without exerting influence on each other, it becomes possible to shorten an inter-chip distance of the plurality of semiconductor chips C on the substrate S. Consequently, it becomes possible to reduce an area of a semiconductor apparatus.

Further, the semiconductor mounting apparatus 1a of the first embodiment adjusts an inter-chip distance of the semiconductor chips C1 and C2 based on captured image of the semiconductor chips C1 and C2.

With this configuration, it becomes possible to appropriately mount the plurality of semiconductor chips C on the substrate S while holding an ideal inter-chip distance that is based on the design information.

### Modified Example 1 of First Embodiment

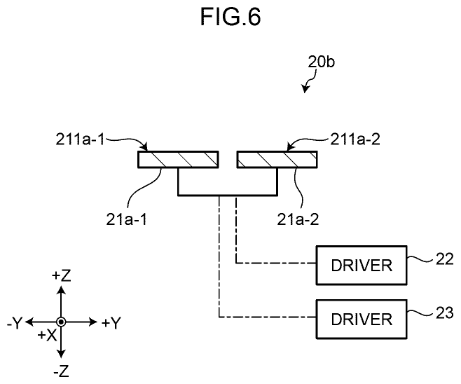

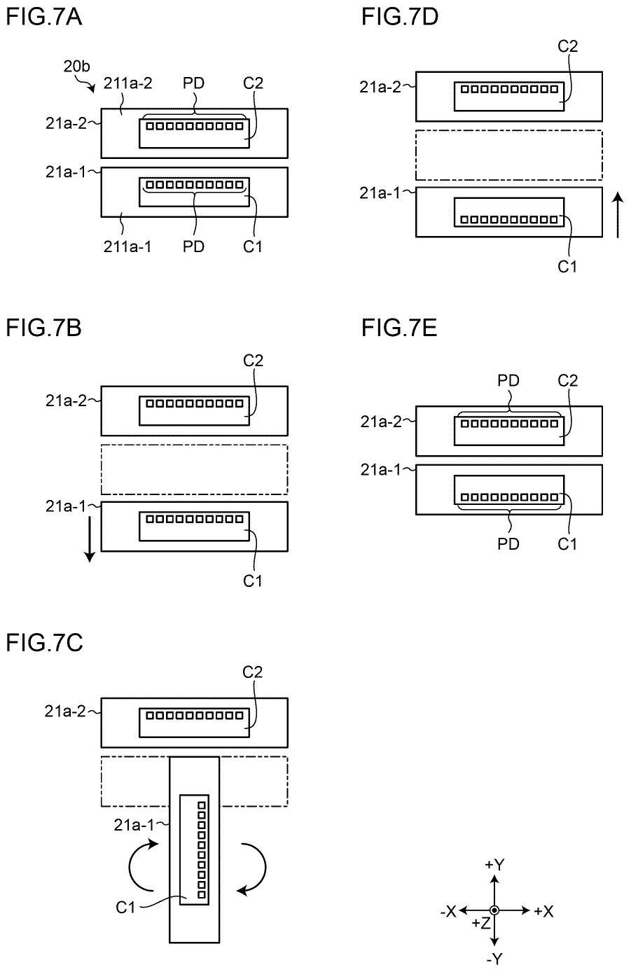

Next, Modified Example 1 of the first embodiment will be described using FIGS. 6 and 7. In the above-described first embodiment, in the semiconductor mounting apparatus 1a, each of the plurality of stages 21a is made movable in the X direction and the Y direction. In contrast to this, in a semiconductor mounting apparatus of Modified Example 1, the plurality of stages 21a is made rotatable along an XY plane. In addition, hereinafter, components similar to those in the above-described first embodiment are assigned similar reference numerals, and the description thereof will be sometimes omitted.

FIG. 6 is a diagram illustrating an example of a configuration of a preciser 20b of Modified Example 1 of the first embodiment.

As illustrated in FIG. 6, the preciser 20b includes a plurality of stages 21a, a driver 22, and a driver 23.

The driver 23 is an actuator including a motor (not illustrated) and the like. The driver 23 rotates each of the plurality of stages 21a along the XY-plane. In accordance with an instruction from the electric controller 40, the driver 23 controls a rotating operation of each of the plurality of stages 21a. With this configuration, it is possible to change the direction along the XY-plane of the plurality of semiconductor chips C placed on the respective placement surfaces 211a. The driver 23 is an example of a second driver.

Hereinafter, change processing of the direction of the semiconductor chip C on the placement surface 211a will be sometimes referred to as “second adjustment processing”.

### Flow of Second Adjustment Processing

FIGS. 7A to 7E are diagrams illustrating an example of a flow of the second adjustment processing in Modified Example 1 of the first embodiment. More specifically, FIGS. 7A to 7E are plan views of the placement surfaces 211a-1 and 211a-2 viewed from above. The second adjustment processing is performed as part of the semiconductor mounting processing.

In addition, in the example in FIGS. 7A to 7E, a case of rotating either one of two stages 21a-1 and 21a-2 will be described.

As illustrated in FIG. 7A, the semiconductor chip C1 is placed on the placement surface 211a-1 of the stage 21a-1, and the semiconductor chip C2 is placed on the placement surface 211a-2 of the stage 21a-2. The semiconductor chips C1 and C2 are placed on the respective placement surfaces 211a-1 and 211a-2 with the ends on the side on which the electrode pads PD are arranged, being oriented toward the positive direction side of the Y direction.

In addition, in this specification, hereinafter, the end of each semiconductor chip C on the side on which the electrode pads PD will be sometimes referred to as a “pad end”. That is, the semiconductor chips C1 and C2 are placed on the respective placement surfaces 211a-1 and 211a-2 with the pad ends being oriented toward the positive direction side of the Y direction.

In FIG. 7A, the imager 330 (FIG. 6) captures the semiconductor chips C1 and C2. Based on the captured image, the electric controller 40 identifies a positional relationship of the semiconductor chips C1 and C2. The positional relationship of the semiconductor chips C1 and C2 is a (current) direction of the respective pad ends of the semiconductor chips C1 and C2 in the preciser 20b, for example.

The electric controller 40 controls the driver 23 based on the identified current direction of the respective pad ends of the semiconductor chips C1 and C2, and design information indicating an ideal direction of the pad ends of the semiconductor chips C1 and C2 to be placed on the substrate S, and rotates at least either one of the stages 21a-1 and 21a-2 along the XY-plane.

In addition, hereinafter, FIGS. 7B to 7E illustrate an operation example of a case of rotating the stage 21a-1 out of the stages 21a-1 and 21a-2, but an operation can be similarly performed in a case of rotating the stage 21a-2.

First of all, as illustrated in FIG. 7B, the driver 23 moves the stage 21a-1 toward the negative direction side of the Y direction. The stage 21a-1 thereby becomes rotatable without coming into contact with the stage 21a-2. Subsequently, as illustrated in FIG. 7C, the driver 23 rotates the stage 21a-1 by 180 degrees. Subsequently, as illustrated in FIG. 7D, the driver 23 returns the stage 21a-1 to an original position by moving the stage 21a-1 toward the positive direction side of the Y direction. The direction of the pad end of the semiconductor chip C1 is accordingly changed to an opposite direction.

Through the above-described process, the second adjustment processing ends.

After the second adjustment processing ends, the electric controller 40 executes the first adjustment processing described with reference to FIGS. 3A and 3B. By executing the above-described first adjustment processing and second adjustment processing, it is possible to arbitrarily change directions and an inter-chip distance of the plurality of semiconductor chips C. Nevertheless, the electric controller 40 may execute the first adjustment processing before executing the second adjustment processing.

According to the semiconductor mounting apparatus and the semiconductor mounting method of Modified Example 1, an effect similar to the semiconductor mounting apparatus 1a and the semiconductor mounting method of the other above-described first embodiment is produced.

### Modified Example 2 of First Embodiment

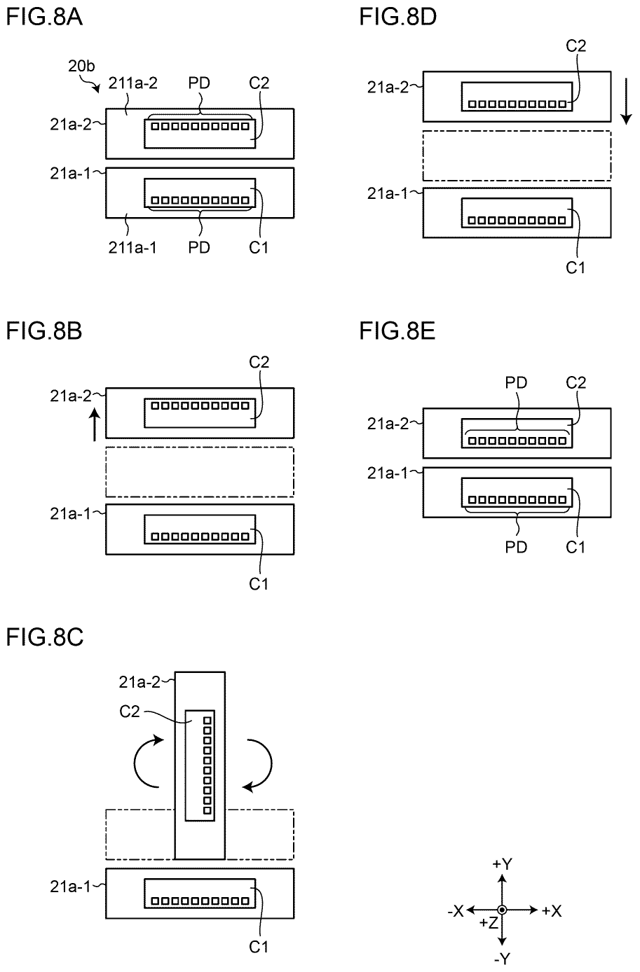

Next, Modified Example 2 of the first embodiment will be described using FIGS. 8A to 8E. A semiconductor mounting apparatus of Modified Example 2 is a modified example of Modified Example 1, and differs from the above-described Modified Example 1 in that the stages 21 a-1 and 21a-2 are rotated. In addition, hereinafter, components similar to those in the above-described Modified Example 1 are assigned similar reference numerals, and the description thereof will be sometimes omitted.

FIGS. 8A to 8E are diagrams illustrating an example of a flow of second adjustment processing in Modified Example 2 of the first embodiment. More specifically, FIGS. 8A to 8E are plan views of the placement surfaces 211a-1 and 211a-2 viewed from above.

In Modified Example 2, precedential to the processing in FIG. 8A, processing corresponding to FIGS. 7A to 7D is executed. By the processing corresponding to FIGS. 7A to 7D, being executed, the semiconductor chip C1 is placed on the placement surface 211a-1 with the pad end being oriented toward the negative direction side of the Y direction, and the semiconductor chip C2 is placed on the placement surface 211a-2 with the pad end being oriented toward the positive direction side of the Y direction.

Subsequently, FIGS. 8B to 8E illustrate an operation example in a case of rotating the stage 21a-2.

First of all, as illustrated in FIG. 8B, the driver 23 moves the stage 21a-2 toward the positive direction side of the Y direction. The stage 21a-2 thereby becomes rotatable without coming into contact with the stage 21a-1. Subsequently, as illustrated in FIG. 8C, the driver 23 rotates the stage 21 a-2 by 180 degrees. Subsequently, as illustrated in FIG. 8D, the driver 23 returns the stage 21a-2 to an original position by moving the stage 21a-2 toward the negative direction side of the Y direction. The direction of the pad end of the semiconductor chip C2 is accordingly changed to an opposite direction.

According to the semiconductor mounting apparatus and the semiconductor mounting method of Modified Example 2, an effect similar to the semiconductor mounting apparatus and the semiconductor mounting method of the above-described Modified Example 1 is produced.

### Second Embodiment

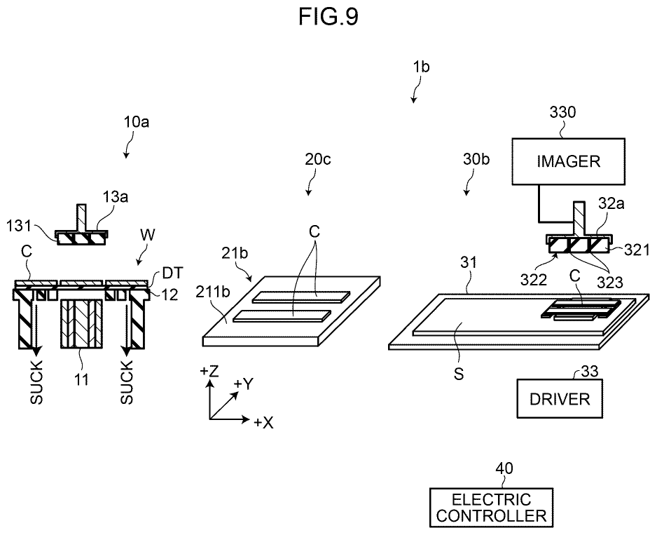

Hereinafter, the second embodiment will be described using FIGS. 9 to 12. In the first embodiment, an inter-chip distance of the plurality of semiconductor chips C is adjusted on the placement surface 211a. In contrast to this, a semiconductor mounting apparatus 1b of the second embodiment adjusts an inter-chip distance of the plurality of semiconductor chips C in the mounting head 32a. In addition, hereinafter, components similar to those in the above-described first embodiment are assigned similar reference numerals, and the description thereof will be sometimes omitted.

Hereinafter, adjustment processing of an inter-chip distance of the plurality of semiconductor chips C in the mounting head 32a will be sometimes referred to as “third adjustment processing”. The details of the third adjustment processing will be described later.

FIG. 9 is a diagram illustrating an example of a configuration of the semiconductor mounting apparatus 1b of the second embodiment.

A preciser 20c of the semiconductor mounting apparatus 1b includes a stage 21b on which the plurality of semiconductor chips C can be placed. The stage 21b has a configuration in which the plurality of semiconductor chips C can be placed on one placement surface 211b. The placement surface 211b is provided with a plurality of suckers (not illustrated) that can individually suck the semiconductor chips C. With this configuration, each of the plurality of semiconductor chips C is held by being sucked to the placement surface 211b. The placement surface 211b is an example of a second placement surface. Nevertheless, the preciser 20b may include a plurality of stages having individual placement surfaces.

A mount apparatus 30b includes a substrate holder 31, a mounting head 32a, and a driver 33. The driver 33 is an example of a third driver.

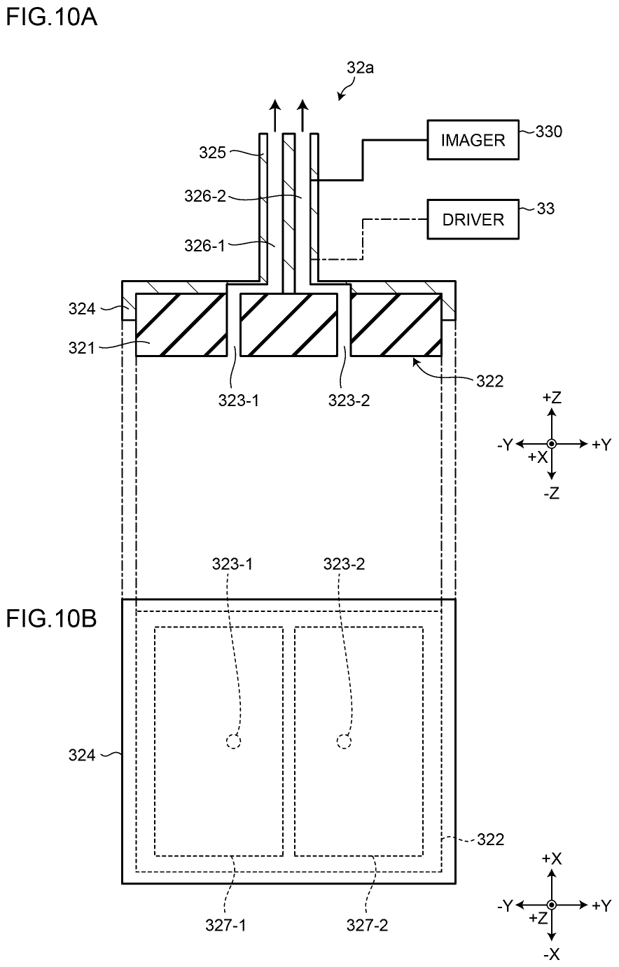

FIGS. 10A and 10B are diagrams illustrating an example of a configuration of the mounting head 32a of the second embodiment.

More specifically, FIG. 10A is a YZ cross-sectional view of the mounting head 32a, and FIG. 10B is a top perspective view of the mounting head 32a viewed from above. In addition, in FIG. 10B, for the sake of explanatory convenience, the illustration of a part of components such as a shaft 325 illustrated in FIG. 10A is omitted.

As illustrated in FIG. 10A, the mounting head 32a includes a suction collet 321 that suck the plurality of semiconductor chips C, a holder 324 that holds the suction collet 321, and the shaft 325 extending upward from an approximately-center part of the holder 324.

The suction collet 321 is formed of rubber, for example. When the semiconductor chip C is picked up from the placement surface 211b (FIG. 9), the bottom surface 322 of the suction collet 321 faces the placement surface 211b. On the bottom surface 322 of the suction collet 321, two suction holes 323-1 and 323-2 are provided along the Y direction, for example. The suction hole 323-1 is arranged on the negative direction side of the Y direction, and the suction hole 323-2 is arranged on the positive direction side of the Y direction. The bottom surface 322 is an example of a suction surface.

The suction hole 323-1 connects with a pipe 326-1 passing through the inside of the shaft 325, and the suction hole 323-2 connects with a pipe 326-2 passing through the inside of the shaft 325. The pipes 326-1 and 326-2 are connected with different vacuum pumps (not illustrated). It is therefore possible to independently vacuum the suction holes 323-1 and 323-2 individually.

Further, hereinafter, a fixed region in the negative direction side of the Y direction of the bottom surface 322 that includes the suction hole 323-1 will be referred to as a suction region 327-1, and a fixed region in the positive direction side of the Y direction that includes the suction hole 323-2 will be referred to as a suction region 327-2. The suction region 327-1 is a region where the semiconductor chip C sucked through the suction hole 323-1 is held, and the suction region 327-2 is a region where the semiconductor chip C sucked through the suction hole 323-2 is held.

Nevertheless, the configuration of the bottom surface 322 of the suction collet 321 such as the number and the positions of suction holes provided in the bottom surface 322, for example, is not limited to the above-described configuration. Further, a plurality of semiconductor chips C may be sucked through one suction hole. Alternatively, one semiconductor chip C may be sucked through a plurality of suction holes.

The driver 33 is an actuator including a motor (not illustrated) and the like. The driver 33 moves the mounting head 32a in the X direction and the Y direction. In accordance with an instruction of the electric controller 40, the driver 33 controls movements in the X direction and the Y direction of the mounting head 32a in picking up a plurality of semiconductor chips C from the placement surface 211b. It is accordingly possible to adjust an inter-chip distance of the plurality of semiconductor chips C in the mounting head 32a.

### Flow of Third Adjustment Processing

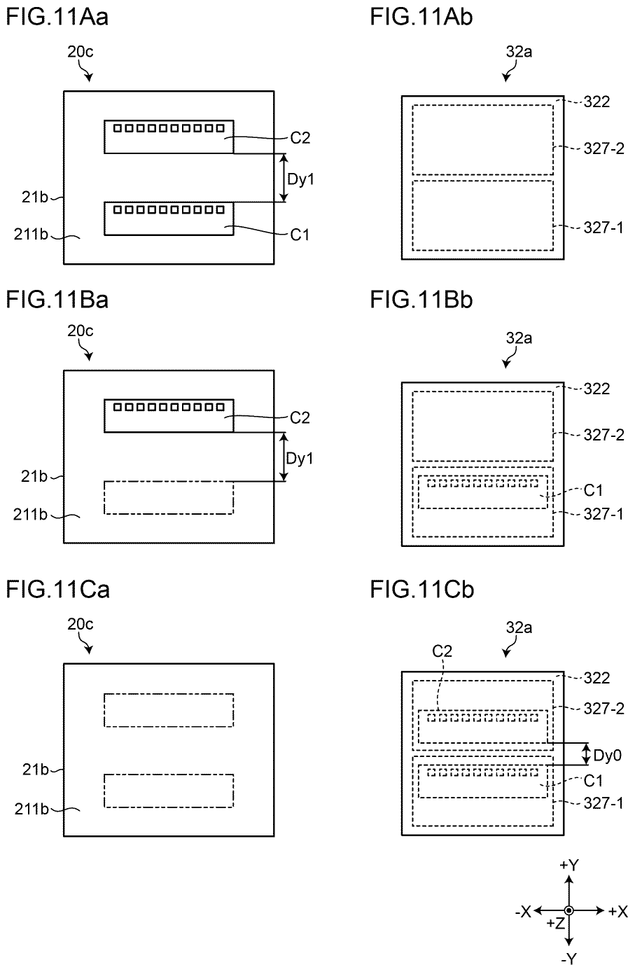

FIG. 11Aa to 11Cb are diagrams illustrating an example of a flow of the third adjustment processing of the second embodiment. The third adjustment processing is performed as part of the semiconductor mounting processing.

FIG. 11Aa to 11Ca are plan views of the placement surface 211b viewed from above. More specifically, FIG. 11Aa to 11Ca illustrate, in a phased manner, a state in which the semiconductor chips C are picked up by the mounting head 32a from the placement surface 211b.

On the other hand, FIG. 11Ab to 11Cb are top perspective views of the mounting head 32a viewed from above. More specifically, FIG. 11Ab to 11Cb illustrate a state in which the semiconductor chips C are sucked to the bottom surface 322 of the mounting head 32a, in such a manner as to correspond to the respective phases in FIG. 11Aa to 11Ca. In addition, in FIG. 11Ab to 11Cb, for the sake of explanatory convenience, the illustration of a part of components such as the suction holes 323-1 and 323-2, and the shaft 325 is omitted.

As illustrated in FIG. 11Aa, the semiconductor chips C1 and C2 are placed on the placement surface 211b in this order from the negative direction side of the Y direction. The semiconductor chips C1 and C2 are placed on the placement surface 211b with the pad ends being oriented toward the positive direction side of the Y direction.

In FIG. 11Aa, the imager 330 (FIG. 10A) captures the semiconductor chips C1 and C2. Based on the captured image, the electric controller 40 identifies a current inter-chip distance of the semiconductor chips C1 and C2. In the example in FIG. 11Aa, the current inter-chip distance of the semiconductor chips C1 and C2 is “Dy1”. On the other hand, it is assumed that an ideal inter-chip distance that is based on design information is “Dy0”.

As described above, as illustrated in FIG. 11Ab, on the bottom surface 322 of the mounting head 32a, the suction regions 327-1 and 327-2 are provided in this order from the negative direction side of the Y direction.

The electric controller 40 moves the mounting head 32a to a position where the suction region 327-1 and the semiconductor chip C1 placed on the placement surface 211b vertically overlap. Subsequently, as illustrated in FIG. 11Ba and 11Bb, the mounting head 32a picks up the semiconductor chip C1 by sucking the semiconductor chip C1 to the suction region 327-1.

Subsequently, the electric controller 40 moves the mounting head 32a to a position where the suction region 327-2 and the semiconductor chip C2 placed on the placement surface 211b vertically overlap. Subsequently, as illustrated in FIG. 11Ca and 11Cb, the mounting head 32a picks up the semiconductor chip C2 by sucking the semiconductor chip C2 to the suction region 327-2.

At this time, the electric controller 40 controls the driver 33 to move the bottom surface 322 in the Y direction, and adjusts a suck position of the semiconductor chip C2 in such a manner that an inter-chip distance of the semiconductor chip C1 sucked to the suction region 327-1, and the semiconductor chip C2 sucked to the suction region 327-2 becomes an ideal inter-chip distance “Dy0” that is based on design information.

As described above, as illustrated in FIG. 11Cb, in the mounting head 32a, an inter-chip distance of the semiconductor chips C1 and C2 is adjusted to “Dy0” being an ideal inter-chip distance that is based on design information.

Through the above-described process, the third adjustment processing ends.

After that, the mounting head 32a lowers toward the substrate S held on the top surface of the substrate holder 31, and pushes the bottom surface 322 against a predetermined position of the substrate S. With this configuration, the semiconductor chips C1 and C2 are placed on the substrate S. The semiconductor chips C1 and C2 are simultaneously placed on the substrate S in a state in which an ideal inter-chip distance (e.g., “Dy0”) adjusted in the third adjustment processing is maintained.

In addition, with reference to FIG. 11Aa to 11Cb, a method of adjusting an inter-chip distance in the Y direction of the semiconductor chips C1 and C2 has been described, but the adjustment of an inter-chip distance in the X direction can also be performed by a similar method.

According to the semiconductor mounting apparatus 1b and the substrate mounting method of the second embodiment, an effect similar to the semiconductor mounting apparatus 1a and the substrate mounting method of the above-described first embodiment is produced.

### Modified Example 1 of Second Embodiment

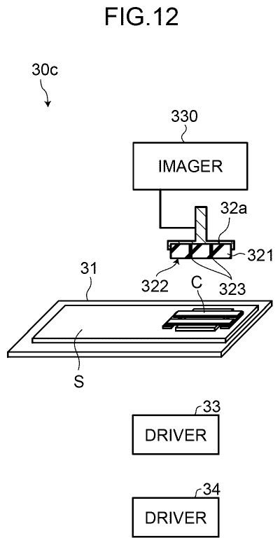

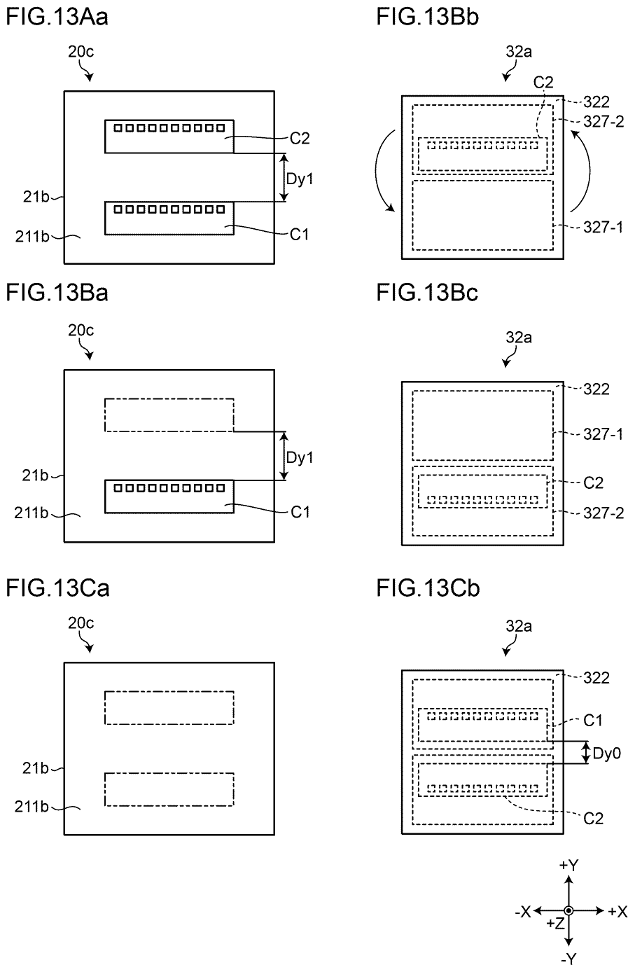

Next, Modified Example 1 of the second embodiment will be described using FIGS. 12 to 13Cb. In the above-described second embodiment, in the semiconductor mounting apparatus 1b, the mounting head 32a is made movable in the X direction and the Y direction. In contrast to this, in a semiconductor mounting apparatus of Modified Example 1, the mounting head 32a is made rotatable along the XY-plane. In addition, hereinafter, components similar to those in the above-described embodiments are assigned similar reference numerals, and the description thereof will be sometimes omitted.

FIG. 12 is a diagram illustrating an example of a configuration of a mount apparatus 30c of Modified Example 1 of the second embodiment.

As illustrated in FIG. 12, the mount apparatus 30c includes a substrate holder 31, a mounting head 32a, a driver 33, and a driver 34.

The driver 34 is an actuator including a motor (not illustrated) and the like. The driver 34 rotates the bottom surface 322 of the mounting head 32a along the XY-plane. In accordance with an instruction from the electric controller 40, the driver 34 controls a rotating operation of the mounting head 32a. With this configuration, it is possible to change a direction along the XY-plane of the plurality of semiconductor chips C sucked by the mounting head 32a. The driver 34 is an example of a fourth driver.

Hereinafter, change processing of the direction of the semiconductor chip C in the mounting head 32a will be sometimes referred to as “fourth adjustment processing”.

### Flow of Fourth Adjustment Processing

FIG. 13Aa to 13Cb are diagrams illustrating an example of a flow of the fourth adjustment processing in Modified Example 1 of the second embodiment. The fourth adjustment processing is performed as part of the semiconductor mounting processing.

FIG. 13Aa to 13Ca are plan views of the placement surface 211b viewed from above. More specifically, FIG. 13Aa to 13Ca illustrate, in a phased manner, a state in which the semiconductor chips C are picked up by the mounting head 32a from the placement surface 211b.

On the other hand, FIG. 13Bb to 13Cb are top perspective views of the mounting head 32a viewed from above. More specifically, FIG. 13Bb to 13Cb illustrate a state in which the semiconductor chips C are sucked to the bottom surface 322 of the mounting head 32a, in such a manner as to correspond to the respective phases in FIG. 13Ba and 13Ca. In addition, in FIG. 13Bb to 13Cb, for the sake of explanatory convenience, the illustration of a part of components such as the suction holes 323-1 and 323-2, and the shaft 325 is omitted.

As illustrated in FIG. 13Aa, on the placement surface 211b, the semiconductor chips C1 and C2 are placed in this order from the negative direction side of the Y direction. The semiconductor chips C1 and C2 are placed on the placement surface 211b with the pad ends being oriented toward the positive direction side of the Y direction.

In FIG. 13Aa, the imager 330 (FIG. 12) captures the semiconductor chips C1 and C2. Based on the captured image, the electric controller 40 identifies a current direction of the respective pad ends of the semiconductor chips C1 and C2.

The electric controller 40 moves the mounting head 32a to a position where the suction region 327-2 and the semiconductor chip C2 placed on the placement surface 211b vertically overlap. As illustrated in FIG. 13Ba and 13Bb, the mounting head 32a picks up the semiconductor chip C2 by sucking the semiconductor chip C2 to the suction region 327-2.

Subsequently, as illustrated in FIG. 13Bb, the electric controller 40 rotates the mounting head 32a by 180 degrees in a direction extending along the XY-plane, in a state in which the semiconductor chip C2 is sucked to the suction region 327-2. With this configuration, the suction region 327-1 moves toward the positive direction side of the Y direction and the suction region 327-2 moves toward the negative direction side of the Y direction, and as illustrated in FIG. 13Bc, the direction of the pad end of the semiconductor chip C2 sucked to the suction region 327-2 can be changed in such a manner as to be oriented toward the negative direction side of the Y direction.

Subsequently, the electric controller 40 moves the mounting head 32a to a position where the suction region 327-1 and the semiconductor chip C1 placed on the placement surface 211b vertically overlap. As illustrated in FIG. 13Ca (Cb), the mounting head 32a picks up the semiconductor chip C1 by sucking the semiconductor chip C1 to the suction region 327-1. With this configuration, it is possible to orient the pad ends of the semiconductor chips C1 and C2 outward.

Through the above-described process, the fourth adjustment processing ends.

In addition, in FIG. 13Ca and 13Cb, when the mounting head 32a picks up the semiconductor chip C1, the electric controller 40 may control the driver 33 to execute the third adjustment processing described with reference to FIG. 11Aa to 11Cb. More specifically, the electric controller 40 may control the driver 33 to move the mounting head 32a in the Y direction, and adjust a suck position of the semiconductor chip C1 in such a manner that an inter-chip distance of the semiconductor chip C2 sucked to the suction region 327-2, and the semiconductor chip C1 sucked to the suction region 327-1 becomes an ideal inter-chip distance (e.g., “Dy0”) that is based on design information.

According to the semiconductor mounting apparatus of Modified Example 1, an effect similar to the semiconductor mounting apparatus and the substrate mounting method of the other above-described second embodiment is produced.

### Modified Example 2 of Second Embodiment

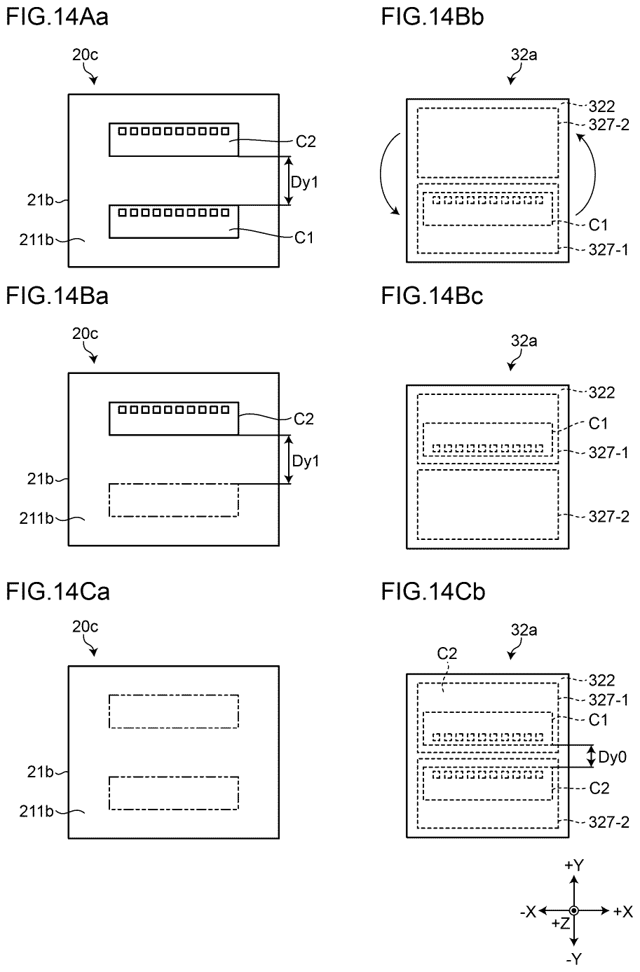

Next, Modified Example 2 of the second embodiment will be described using FIG. 14Aa to 14Cb. A semiconductor mounting apparatus of Modified Example 2 is a modified example of Modified Example 1, and differs from Modified Example 1 in the direction of pad ends of the semiconductor chips C1 and C2 after the execution of the fourth adjustment processing. In addition, hereinafter, components similar to those in the above-described embodiments are assigned similar reference numerals, and the description thereof will be sometimes omitted.

FIG. 14Aa to 14Cb are diagrams illustrating an example of a flow of the fourth adjustment processing of Modified Example 2 of the second embodiment.

FIG. 14Aa to 14Ca are plan views of the placement surface 211b viewed from above. More specifically, FIG. 14Aa to 14Ca illustrate, in a phased manner, a state in which the semiconductor chips C are picked up by the mounting head 32a from the placement surface 211b.

On the other hand, FIG. 14Bb to 14Cb are top perspective views of the mounting head 32a viewed from above. More specifically, FIG. 14Bb to 14Cb illustrate a state in which the semiconductor chips C are sucked to the bottom surface 322 of the mounting head 32a, in such a manner as to correspond to the respective phases in FIG. 14Ba and 14Ca. In addition, in FIG. 14Bb to 14Cb, for the sake of explanatory convenience, the illustration of a part of components such as the suction holes 323-1 and 323-2, and the shaft 325 is omitted.

As illustrated in FIG. 14Aa, on the placement surface 211b, the semiconductor chips C1 and C2 are placed in this order from the negative direction side of the Y direction. The semiconductor chips C1 and C2 are placed on the placement surface 211b with the pad ends being oriented toward the positive direction side of the Y direction.

First of all, the electric controller 40 moves the mounting head 32a to a position where the suction region 327-1 and the semiconductor chip C1 placed on the placement surface 211b vertically overlap. As illustrated in FIG. 14Ba and 14Bb, the mounting head 32a picks up the semiconductor chip C1 by sucking the semiconductor chip C1 to the suction region 327-1.

Subsequently, as illustrated in FIG. 14Bb, the electric controller 40 rotates the mounting head 32a by 180 degrees in a state in which the semiconductor chip C1 is sucked to the suction region 327-1. With this configuration, the suction region 327-1 moves toward the positive direction side of the Y direction and the suction region 327-2 moves toward the negative direction side of the Y direction, and as illustrated in FIG. 14Bc, the direction of the pad end of the semiconductor chip C1 sucked to the suction region 327-1 can be changed in such a manner as to be oriented toward the negative direction side of the Y direction.

Subsequently, the electric controller 40 moves the mounting head 32a to a position where the suction region 327-2 and the semiconductor chip C2 placed on the placement surface 211b vertically overlap. As illustrated in FIG. 14Ca and 14Cb, the mounting head 32a picks up the semiconductor chip C2 by sucking the semiconductor chip C2 to the suction region 327-2. With this configuration, it is possible to orient the pad end of the semiconductor chip C2 toward the positive direction side of the Y direction. That is, it is possible to orient the pad ends of the semiconductor chips C1 and C2 inward.

According to the semiconductor mounting apparatus of Modified Example 2, an effect similar to the semiconductor mounting apparatus and the substrate mounting method of the above-described Modified Example 1 is produced.

### Third Embodiment

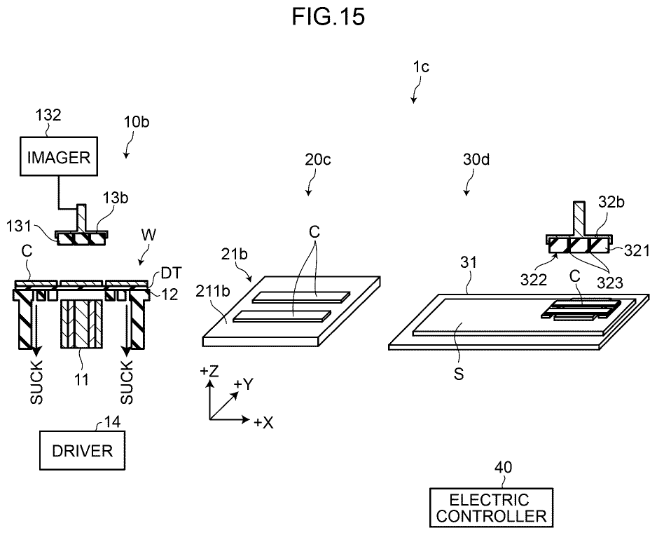

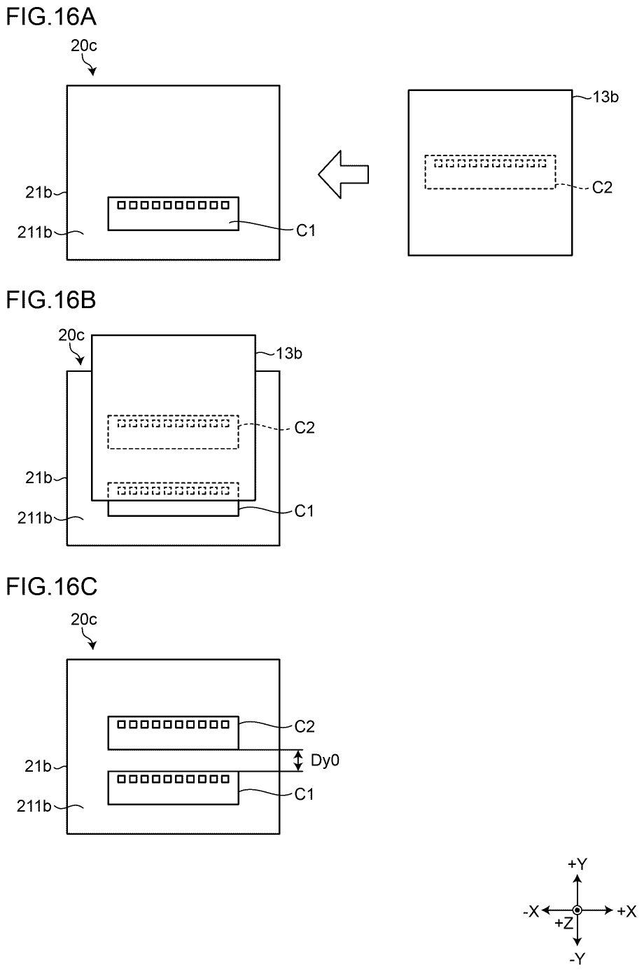

Hereinafter, the third embodiment will be described using FIGS. 15 to 16C. A semiconductor mounting apparatus 1c of the third embodiment differs from the above-described first and second embodiments in that an inter-chip distance of a plurality of semiconductor chips C is adjusted in a transfer head 13b. More specifically, in the semiconductor mounting apparatus 1c, the transfer head 13b includes an imager 132, and a mounting head 32b does not include the imager 330. In addition, hereinafter, components similar to those in the above-described embodiments are assigned similar reference numerals, and the description thereof will be sometimes omitted.

Hereinafter, adjustment processing of an inter-chip distance of the plurality of semiconductor chips C in the transfer head 13a will be sometimes referred to as “fifth adjustment processing”. The details of the fifth adjustment processing will be described later.

FIG. 15 is a diagram illustrating an example of a configuration of the semiconductor mounting apparatus 1c of the third embodiment.

A pickup apparatus 10b of the semiconductor mounting apparatus 1c includes a thrusting mechanism 11, a wafer holder 12, the transfer head 13b, and a driver 14.

The driver 14 is an actuator including a motor (not illustrated) and the like. The driver 14 moves the transfer head 13b in the X direction and the Y direction. In accordance with an instruction from the electric controller 40, the driver 14 controls operations in the X direction and the Y direction of the transfer head 13b when placing the semiconductor chip C on the placement surface 211b. With this configuration, it is possible to adjust an inter-chip distance of the plurality of semiconductor chips C to be placed on the placement surface 211b. The driver 14 is an example of a fifth driver.

The transfer head 13b includes the imager 132. For example, the imager 132 is a camera, and is attached to an upper part of the transfer head 13b. The imager 132 captures a semiconductor chip C placed on the placement surface 211b earlier, from above. Before second and subsequent semiconductor chips C are placed on the placement surface 211b, the imager 132 performs the above-described image capturing. The imager 132 transmits the captured image to the electric controller 40. The captured image is used for the fifth adjustment processing in the electric controller 40. The imager 132 is an example of a second imager.

### Flow of Fifth Adjustment Processing

FIGS. 16A to 16C are diagrams illustrating an example of a flow of the fifth adjustment processing in the third embodiment. The fifth adjustment processing is performed as part of the semiconductor mounting processing.

FIGS. 16A to 16C are plan views of the placement surface 211b viewed from above. More specifically, FIGS. 16A to 16C illustrate, in a phased manner, a state in which the semiconductor chips C are placed on the placement surface 211b by the transfer head 13b. Further, in FIG. 16B, to illustrate a state in which the adjustment of an inter-chip distance of the semiconductor chips C1 and C2 is performed in the transfer head 13b, the transfer head 13b is displayed with being superimposed on the placement surface 211b.

As illustrated in FIG. 16A, the semiconductor chip C1 is placed on the placement surface 211b. The semiconductor chip C1 is placed on the placement surface 211b earlier among the plurality of semiconductor chips C. The transfer head 13b that has placed the semiconductor chip C1 on the placement surface 211b returns to the pickup apparatus 10b (FIG. 15), and holds the semiconductor chip C2 by picking up the semiconductor chip C2 from the thrusting mechanism 11. The semiconductor chip C2 is a semiconductor chip C to be placed on the placement surface 211b next.

Subsequently, as illustrated in FIG. 16B, the electric controller 40 moves the transfer head 13b to a position vertically overlapping the placement surface 211b.

The imager 132 (FIG. 15) captures the semiconductor chip C1 placed on the placement surface 211b. The electric controller 40 controls the transfer head 13b based on the captured image, and places the semiconductor chip C2 at a position neighboring the semiconductor chip C1. The captured image includes positional information of the semiconductor chip C1 on the placement surface 211b.

At this time, the electric controller 40 controls the driver 14, and changes a placement position of the semiconductor chip C2 in such a manner that an inter-chip distance of the semiconductor chip C1 placed on the placement surface 211b, and the semiconductor chip C2 to be placed next becomes “Dy0”, for example, serving as an ideal inter-chip distance that is based on design information.

As described above, as illustrated in FIG. 16C, an inter-chip distance of the semiconductor chips C1 and C2 to be placed on the placement surface 211b is adjusted to an ideal inter-chip distance that is based on design information.

Through the above-described process, the fifth adjustment processing ends.

After that, the mounting head 32b picks up the semiconductor chips C1 and C2 from the placement surface 211b. With this configuration, the semiconductor chips C1 and C2 are sucked by the mounting head 32b in a state in which the ideal inter-chip distance (e.g., “Dy0”) is maintained. Subsequently, the mounting head 32b lowers toward the substrate S held on the top surface of the substrate holder 31, and places the semiconductor chips C1 and C2 at predetermined positions on the substrate S. The semiconductor chips C1 and C2 are simultaneously placed on the substrate S in a state in which the ideal inter-chip distance (e.g., “Dy0”) adjusted by the fifth adjustment processing is maintained.

According to the semiconductor mounting apparatus 1c of the third embodiment, an effect similar to the semiconductor mounting apparatus and the substrate mounting method of the other above-described first and second embodiments is produced.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor mounting apparatus comprising:
an electronic component holder on which two or more semiconductor chips having first surfaces provided with an adhesive agent are placeable;
a substrate holder that holds a substrate on which the two or more semiconductor chips are to be mounted; and
a mounting head that picks up the two or more semiconductor chips from the substrate holder, and mounts the picked-up two or more semiconductor chips on the substrate in such a manner that the first surfaces face the substrate.

2. The semiconductor mounting apparatus according to claim 1, wherein
the mounting head includes a first imager that captures the two or more semiconductor chips placed on the electronic component holder, and
the semiconductor mounting apparatus further comprises an electric controller that controls either the electronic component holder or the mounting head based on a captured image of the two or more semiconductor chips that have been captured by the first imager, and adjusts an inter-chip distance, on the substrate, between the two or more semiconductor chips to be mounted on the substrate.

3. The semiconductor mounting apparatus according to claim 2, wherein
the electronic component holder includes:
two or more stages having first placement surfaces on which the two or more semiconductor chips are placeable; and
a first driver that is capable of moving each of the two or more stages in a first direction extending along the first placement surface, and a second direction that extends along the first placement surface and intersects with the first direction, and
the electric controller controls the first driver based on the captured image, and adjusts the inter-chip distance by moving at least any of the two or more stages in at least either of the first direction and the second direction.

4. The semiconductor mounting apparatus according to claim 3, wherein
the electronic component holder further includes a second driver that rotates each of the two or more stages in a direction extending along the first placement surface, and
the electric controller controls the second driver based on the captured image, and by rotating at least any stage of the two or more stages, changes a direction of a semiconductor chip placed on the first placement surface of the rotated stage.

5. The semiconductor mounting apparatus according to claim 2, wherein
the electronic component holder has a second placement surface on which the two or more semiconductor chips are placeable,
the mounting head includes:
a suction surface that is configured to be arranged to face the second placement surface, and sucks and picks up the two or more semiconductor chips placed on the second placement surface one by one; and
a third driver that is capable of moving the suction surface in a first direction extending along the second placement surface, and a second direction that extends along the second placement surface and intersects with the first direction, and
the electric controller controls the third driver based on the captured image, and adjusts the inter-chip distance by moving the suction surface in at least either of the first direction and the second direction, and changing a suck position on the suction surface of at least any semiconductor chip of the two or more semiconductor chips placed on the second placement surface.

6. The semiconductor mounting apparatus according to claim 5, wherein
the mounting head further includes a fourth driver that is capable of rotating the suction surface in a direction extending along the second placement surface, and
the electric controller controls the fourth driver based on the captured image, and changes a direction of at least any of the two or more semiconductor chips by rotating the suction surface in the direction extending along the second placement surface.

7. The semiconductor mounting apparatus according to claim 1, wherein
the electronic component holder has a second placement surface on which the two or more semiconductor chips are placeable,
the semiconductor mounting apparatus further comprises a transfer head that places the two or more semiconductor chips singulated from a wafer, on the second placement surface one by one,
the two or more semiconductor chips include a first semiconductor chip, and a second semiconductor chip to be placed on the second placement surface next to the first semiconductor chip,
the transfer head is configured to hold at least one semiconductor chip,
the transfer head includes:
a second imager that captures the first semiconductor chip placed on the second placement surface; and
a fifth driver that is capable of moving the transfer head in a first direction extending along the second placement surface, and a second direction that extends along the second placement surface and intersects with the first direction, and
the semiconductor mounting apparatus further comprises an electric controller that controls the fifth driver based on a second captured image indicating positional information of the first semiconductor chip that has been captured by the second imager, and adjusts an inter-chip distance between the two or more semiconductor chips on the second placement surface by moving the transfer head holding the second semiconductor chip, in at least either of the first direction and the second direction, and changing a placement position of the second semiconductor chip on the second placement surface.

8. The semiconductor mounting apparatus according to claim 1, wherein the mounting head simultaneously places the two or more semiconductor chips on the substrate.

9. A semiconductor mounting method comprising:
placing, on an electronic component holder, two or more semiconductor chips having first surfaces provided with an adhesive agent;
picking up the two or more semiconductor chips from the electronic component holder, and transferring the two or more semiconductor chips to a substrate holder that holds a substrate on which the two or more semiconductor chips are to be mounted; and
placing the two or more semiconductor chips on the substrate in such a manner that the first surfaces face the substrate.

10. The semiconductor mounting method according to claim 9, wherein, when the two or more semiconductor chips are placed on the substrate, based on a captured image of the two or more semiconductor chips placed on the electronic component holder, an inter-chip distance, on the substrate, between the two or more semiconductor chips to be mounted on the substrate is adjusted.

11. The semiconductor mounting method according to claim 10, wherein
the electronic component holder includes two or more stages having first placement surfaces on which the two or more semiconductor chips are placeable, and
adjusting the inter-chip distance includes moving, based on the captured image, at least any of the two or more stages in at least either of a first direction extending along the first placement surface, and a second direction that extends along the first placement surface and intersects with the first direction.

12. The semiconductor mounting method according to claim 11, wherein
when the two or more semiconductor chips are picked up from the electronic component holder, by rotating at least any stage of the two or more stages based on the captured image, a direction of a semiconductor chip placed on the first placement surface of the rotated stage is changed.

13. The semiconductor mounting method according to claim 10, wherein
the electronic component holder includes a second placement surface on which the two or more semiconductor chips are placeable,
a mounting head including a suction surface that is configured to be arranged to face the second placement surface, and sucks and picks up the two or more semiconductor chips placed on the second placement surface one by one is prepared, and
adjusting the inter-chip distance includes changing a suck position on the suction surface of at least any semiconductor chip of the two or more semiconductor chips placed on the second placement surface, by moving, based on the captured image, the suction surface of the mounting head in at least either of a first direction extending along the second placement surface, and a second direction that extends along the second placement surface and intersects with the first direction.

14. The semiconductor mounting method according to claim 13, wherein
when the two or more semiconductor chips placed on the second placement surface are sucked and picked up one by one, by rotating the suction surface in a direction extending along the second placement surface, based on the captured image, a direction of at least any semiconductor chip of the two or more semiconductor chips is changed.

15. The semiconductor mounting method according to claim 9, wherein
the electronic component holder has a second placement surface on which the two or more semiconductor chips are placeable,
a transfer head that places the two or more semiconductor chips singulated from a wafer, on the second placement surface one by one is prepared,
the two or more semiconductor chips include a first semiconductor chip, and a second semiconductor chip to be placed on the second placement surface next to the first semiconductor chip, and
adjusting an inter-chip distance between the two or more semiconductor chips on the second placement surface includes changing a placement position of the second semiconductor chip on the second placement surface by moving, based on a second captured image of the first semiconductor chip that indicates positional information of the first semiconductor chip placed on the second placement surface of the electronic component holder, the transfer head holding the second semiconductor chip, in at least either of a first direction extending along the second placement surface, and a second direction that extends along the second placement surface and intersects with the first direction.

16. The semiconductor mounting method according to claim 9, wherein
when the two or more semiconductor chips are placed on the substrate, the two or more semiconductor chips are simultaneously placed on the substrate.
